(19) United States
(12) Patent Application Publication
(10) Pub. No.: US 2014/0042463 A1
(43) Pub. Date: Feb. 13, 2014

(54) OPTOELECTRONIC INTEGRATED PACKAGE MODULE

(71) Applicant: KABUSHIKI KAISHA TOSHIBA, Tokyo (JP)

(72) Inventors: Hiroshi UEMURA, Yokohama-shi (JP); Hideto FURUYAMA, Yokohama-shi (JP)

(73) Assignee: KABUSHIKI KAISHA TOSHIBA, Tokyo (JP)

(21) Appl. No.: 13/840,461

(22) Filed: Mar. 15, 2013

(30) Foreign Application Priority Data
Aug. 13, 2012 (JP) 2012-179447

(51) Int. Cl. H01L 31/12

(52) U.S. Cl. CPC H01L 31/12
USPC 257/80

(57) ABSTRACT

According to one embodiment, there is provided an optoelectronic integrated package module including a silicon interposer that has an electrical interconnection and an optical waveguide, and formed on a silicon substrate, an optical semiconductor element formed in the silicon interposer, and electrically connected to the electrical interconnection and optically coupled to the optical waveguide, an electrical circuit element formed in the silicon interposer, and electrically connected to the optical semiconductor element, and a semiconductor integrated circuit chip mounted on the silicon interposer, and electrically connected to the electrical circuit element. The semiconductor integrated circuit chip transmits an electrical signal to the optical semiconductor element via the electrical circuit element or receives an electrical signal from the optical semiconductor element via the electrical circuit element.

### CROSS-REFERENCE TO RELATED APPLICATIONS

This application is based upon and claims the benefit of priority from Japanese Patent Application No. 2012-179447, filed Aug. 13, 2012, the entire contents of which are incorporated herein by reference.

### FIELD

Embodiments described herein relate generally to an optoelectronic integrated package module.

### BACKGROUND

Recently, with improvements in the performance of electronic devices and increases in the volume of multimedia contents, the amount of signal processing in information communication devices has increased. With this increase, the signal transmission rates of interconnections inside and outside electronic devices have increased. This arises the problems of transmission loss and electromagnetic noise interference. A great deal of attention has therefore been paid to optical signal transmission having features of being high-speed and low in noise, and various types of optoelectronic integrated package modules have been proposed.

### BRIEF DESCRIPTION OF THE DRAWINGS

FIG. 1A is a plan view showing the schematic arrangement of an optoelectronic integrated package module according to the first embodiment;

FIG. 1B is a sectional view showing the schematic arrangement of the optoelectronic integrated package module according to the first embodiment;

FIG. 1C is a circuit diagram for explaining the schematic arrangement of the optoelectronic integrated package module according to the first embodiment;

FIG. 2 is a graph showing the current-voltage characteristics of an electrical circuit element and light-emitting element;

FIG. 3 is a sectional view showing a state in which an optoelectronic integrated package module in FIG. 1B is coated with a mold resin;

FIGS. 4A to 4C are sectional views of steps for explaining the process of forming an optical waveguide;

FIGS. 5A to 5G are sectional views of steps for explaining the process of forming an optical semiconductor element and an electrical circuit element;

FIG. 6 is a plan view showing a state in which a multilayer structure is patterned into a ring shape in the step of FIG. 5D;

FIG. 7A is a plan view showing the schematic arrangement of an optoelectronic integrated package module according to the second embodiment;

FIG. 7B is a sectional view showing the schematic arrangement of the optoelectronic integrated package module according to the second embodiment;

FIG. 7C is a circuit diagram showing the schematic arrangement of the optoelectronic integrated package module according to the second embodiment;

FIGS. 8A to 8F are sectional views for explaining the process of forming interconnection vias;

FIG. 9 is a waveform chart showing the occurrence of ringing at the rising and falling edges of an electrical signal;

FIG. 10A is a plan view showing the schematic arrangement of an optoelectronic integrated package module according to the third embodiment;

FIG. 10B is a sectional view showing the schematic arrangement of an optoelectronic integrated package module according to the third embodiment;

FIG. 11 is a schematic circuit diagram showing an arrangement of an optoelectronic integrated package module which corresponds to the transmission side according to the fourth embodiment; and

FIGS. 12A to 12G are sectional views of steps for explaining the process of forming an optical semiconductor element of an optoelectronic integrated package module according to the fifth embodiment.

### DETAILED DESCRIPTION

In general, according to one embodiment, there is provided an optoelectronic integrated package module comprising: a silicon interposer formed on a silicon substrate, the interposer including an electrical interconnection and an optical waveguide; an optical semiconductor element formed in the silicon interposer, the optical semiconductor element being electrically connected to the electrical interconnection and optically coupled to the optical waveguide; an electrical circuit element formed in the silicon interposer, the electrical circuit element being electrically connected to the optical semiconductor element; and a semiconductor integrated circuit chip mounted on the silicon interposer, the integrated circuit chip being electrically connected to the electrical circuit element.

The semiconductor integrated circuit chip transmits an electrical signal to the optical semiconductor element via the electrical circuit element or receives an electrical signal from the optical semiconductor element via the electrical circuit element.

An optoelectronic integrated package module according to an embodiment will be described below with reference to the accompanying drawing.

### First Embodiment

### <Arrangement of Optoelectronic Integrated Package Module>

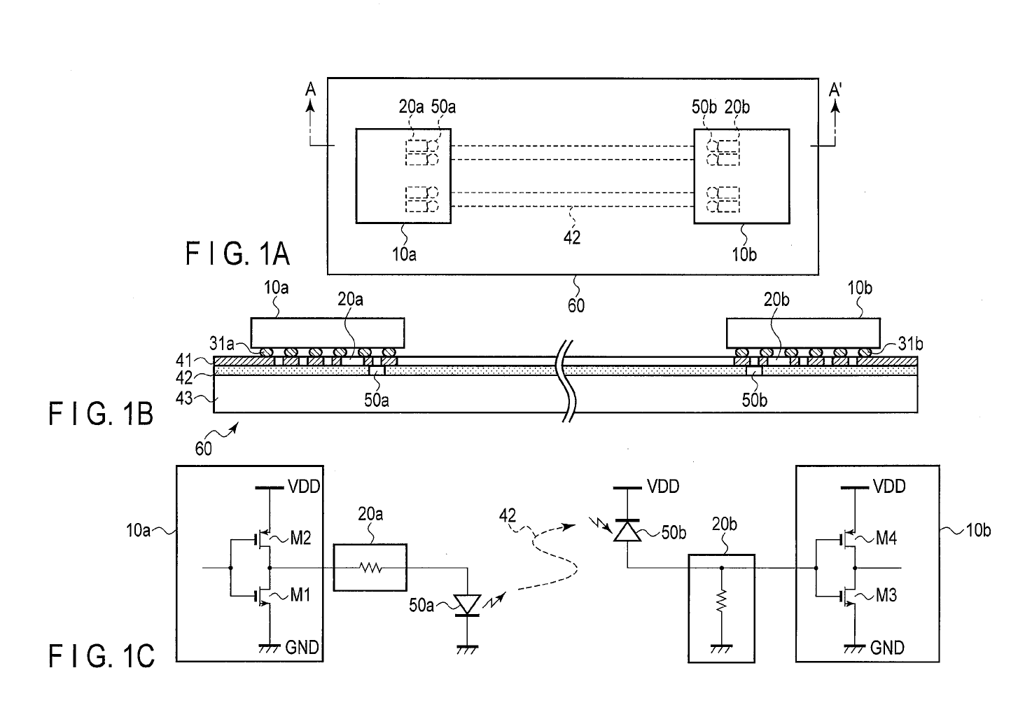

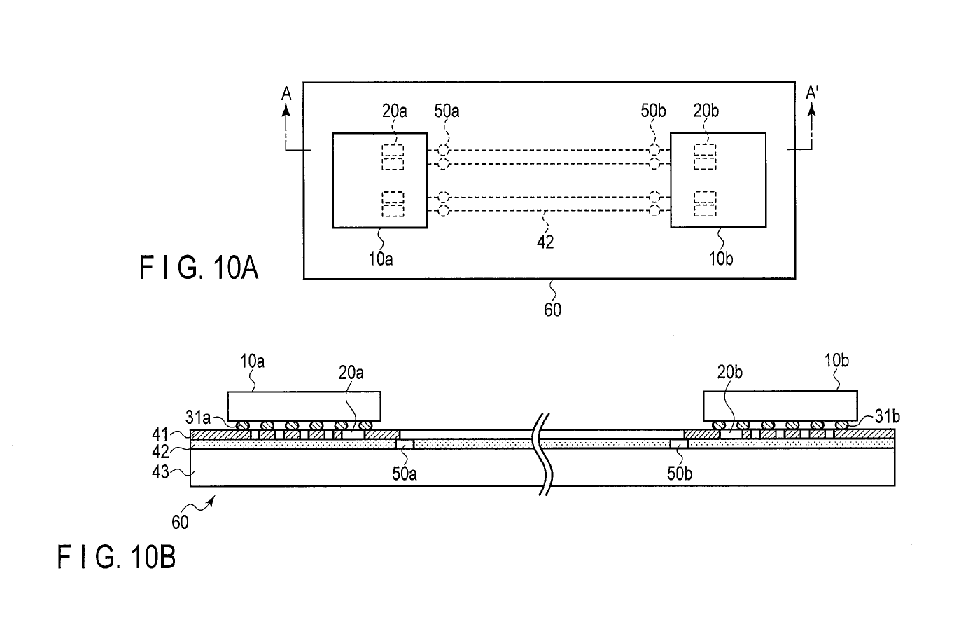

FIGS. 1A to 1C are views for explaining the schematic arrangement of an optoelectronic integrated package module according to the first embodiment. FIG. 1A is a plan view of the optoelectronic integrated package module. FIG. 1B is a sectional view taken along A-A′ in FIG. 1A. FIG. 10 is a circuit diagram of the optoelectronic integrated package module.

The optoelectronic integrated package module according to this embodiment is formed by mounting semiconductor integrated circuit chips 10, i.e., 10a and 10b, on a silicon interposer 60 including a silicon substrate 43, electrical circuit elements 20, i.e., 20a and 20b, electrical interconnections 41, optical waveguides 42, and optical semiconductor elements 50, i.e., 50a and 50b.

The optical semiconductor elements 50 are arranged on the silicon substrate 43 of the silicon interposer 60 so as to be spaced apart from each other. One of the optical semiconductor elements 50 is the light-emitting element 50a, and the other is the light-receiving element 50b. The semiconductor integrated circuit chips 10 and the electrical circuit elements 20 are respectively provided on the light-emitting element 50a side and the light-receiving element 50b side. The first electrical circuit element 20a is provided in the silicon interposer 60 on the light-emitting element 50a side. The second electrical circuit element 20b is provided in the silicon interposer 60 on the light-receiving element 50b side. The first semiconductor integrated circuit chip 10a is mounted on the silicon interposer 60 on the light-emitting element 50a side. The second semiconductor integrated circuit chip 10b is mounted on the silicon interposer 60 on the light-receiving element 50b side.

The semiconductor integrated circuit chip 10 is a 10 mm×10 mm system LSI manufactured by a 22 nm generation CMOS process. This chip performs various types of numerical calculations and information processing, device control, and the like. The semiconductor integrated circuit chips 10 are mounted on bumps 31, i.e., 31a and 31b, each having a diameter of 50 μm, arranged on the silicon interposer 60 at a pitch of 100 μm, and are electrically connected to the electrical interconnections 41 of the silicon interposer 60.

Assume that the silicon interposer 60 is obtained by forming the electrical circuit elements 20, i.e., 20a and 20b, the electrical interconnections 41, the optical waveguides 42, and the optical semiconductor elements 50, i.e., 50a and 50b, on the silicon substrate 43, and has a size of 30 mm×20 mm and a thickness of 400 μm.

The optical waveguide 42 is, for example, an optical waveguide with the cladding being formed from a silicon oxide film and the core being formed from silicon. The core has a sectional area of 300 nm×300 nm. The optical waveguide 42 can confine light in the core having a higher refractive index than the cladding. This allows an optical signal to propagate along the optical waveguide 42.

The optical semiconductor element 50 is an optical semiconductor element having, for example, a ring-like shape with an external diameter of 50 μm and an inner diameter of 30 μm. The light-emitting element 50a converts an electrical signal (current signal) into an optical signal. The light-receiving element 50b converts an optical signal into an electrical signal (current signal). The optical semiconductor element 50 is electrically connected to the electrical interconnection 41 and optically coupled to the optical waveguide 42. It is possible to perform electrical signal input/output operation between the light-emitting element 50a and the light-receiving element 50b by optical signal transmission.

The light-emitting element 50a is more specifically a laser diode element. When a current flows in the light-emitting element 50a, carriers are injected into the active layer to cause induced emission by the recombination of the injected carriers. The light generated by induced emission circulates in a ring-like resonator owing to total reflection, and causes laser oscillation at a specific wavelength determined by the ring circumferential length.

The light-receiving element 50b is, more specifically, a photodiode element. In the light-receiving element 50b, when an optical signal enters the depletion layer of the p-n junction portion, an electrical signal is generated by carrier excitation. In addition, applying a voltage in the reverse direction of the diode to the light-receiving element 50b can improve sensitivity and increase the response speed.

More specifically, the optical semiconductor elements 50 are optically coupled to the optical waveguides 42 by distributed coupling (or evanescent coupling). That is, although the optical semiconductor elements 50 are not in direct contact with the optical waveguides 42, an exuding component (evanescent component) from the light-emitting element 50a is coupled to the optical waveguide 42 or an exuding component from the optical waveguide 42 is coupled to the light-receiving element 50b. This implements optical coupling between the optical semiconductor elements 50 and the optical waveguides 42. Such optical coupling obviates the necessity to use a spot size converter which increases or decreases a beam diameter and a deflecting mirror which performs optical path conversion. This can not only simplify the process of forming the silicon interposer 60 but also reduce the size and thickness of the silicon interposer 60.

In order to manufacture the optical semiconductor element 50, for example, as will be described later, a 1-μm-thick multilayer structure formed on a compound semiconductor substrate is bonded onto the silicon substrate 43 in which the optical waveguides 42 are formed. Subsequently, the optical semiconductor element 50 is formed on the silicon substrate 43 (in the silicon interposer 60) by patterning the structure upon alignment with the optical waveguide 42. This makes it possible to accurately align the optical semiconductor element 50 with the optical waveguide 42, thereby achieving high optical coupling efficiency.

Note that the optical semiconductor elements 50 are not optical semiconductor elements which are formed from different chips and mounted on the silicon substrate 43 or the silicon interposer 60. The optical semiconductor elements 50 are formed on the silicon substrate 43 by direct patterning and embedded in the silicon interposer 60. That is, the optical semiconductor elements 50 are arranged below (on the silicon substrate 43 side) the electrical interconnections 41 and completely embedded in an insulator. These elements are not therefore exposed on the surface of the silicon interposer 60. This protects the surfaces of the optical semiconductor elements 50, and can prevent the optical semiconductor elements 50 from being damaged by heating and physical impact when mounting the semiconductor integrated circuit chips 10 (described later). In addition, it is possible to implement the above high optical coupling efficiency and compact optical coupling by distributed coupling.

In contrast, the following problems arise if edge emitting semiconductor laser chips, vertical cavity surface emitting laser (VCSEL) chips, or surface incident photodiode chips are used as the optical semiconductor elements 50, and are mounted on the silicon interposer 60 by die bonding. That is, a mounting position shift (for example, 10 μm) larger than the size of the optical waveguide 42 (the sectional size is 300 nm×300 nm in this case) may occur to lead to a considerable deterioration in optical coupling efficiency. In addition, to implement optical coupling to the optical waveguide 42, it is necessary to form a spot size converter which increases or decreases a beam diameter and a 45° mirror for optical path conversion at an optical coupling portion with the optical waveguide. This complicates the process of forming the silicon interposer 60 and also increases the size or thickness of the silicon interposer 60.

The electrical circuit element 20 is, for example, a 100-nm-thick thin film resistor made of a cermet material such as Ta—SiO₂, and has a size of 50 μm×50 μm with a resistance of 1 kΩ. The electrical circuit elements 20 are formed on the electrical interconnections 41 to be electrically connected to the optical semiconductor elements 50. Like the optical semiconductor elements 50, an insulating film is formed on the upper layers of the electrical circuit elements 20 to embed them in the silicon interposer 60. That is, the upper layers of the electrical circuit elements 20 are completely covered by an insulator so as not be exposed on the surface of the silicon interposer 60. This protects the surfaces of the electrical circuit elements 20, and can prevent the electrical circuit elements 20 from being damaged by heating and physical impact when mounting the semiconductor integrated circuit chips 10 (described later).

The electrical interconnection 41 is formed from, for example, a 1-μm-thick multilayer member having a Ti/Pt/Au three-layer structure. It is preferable to form, for example, a photosensitive polyimide film on the electrical interconnections 41 and the electrical circuit elements 20 and then pattern the film. This protects and insulates the surfaces of them and also forms electrical connection terminals by partly exposing the electrical interconnections 41.

### <Signal Transmitting Operation>

As described above, the semiconductor integrated circuit chips 10 are mounted on the soldering bumps 31 on the silicon interposer 60 and electrically connected to the electrical circuit elements 20. Semiconductor integrated circuit chip 10a transmits an electrical signal to the light-emitting element 50a via electrical circuit element 20a. The light-emitting element 50a converts the received electrical signal (current signal) into an optical signal and transmits it. The light-receiving element 50b converts the received optical signal into an electrical signal (current signal) and outputs it. Semiconductor integrated circuit chip 10b receives the electrical signal output from the light-receiving element 50b via electrical circuit element 20b. This can implement high-speed, low-noise optical signal transmission from semiconductor integrated circuit chip 10a to semiconductor integrated circuit chip 10b. Assume that the optical signal transmission rate is, for example, 10 Gbps or more.

As shown in FIG. 1C, semiconductor integrated circuit chip 10a includes, as an interface circuit (transmission circuit), for example, a CMOS inverter circuit constituted by an nMOS transistor M1 and a pMOS transistor M2. Semiconductor integrated circuit chip 10b includes, as an interface circuit (reception circuit), for example, a CMOS inverter circuit constituted by an nMOS transistor M3 and a pMOS transistor M4.

On the semiconductor integrated circuit chip 10a side, when the output is at high level (when the pMOS transistor M2 is on), an optical signal is generated by making a current flow from a power supply potential VDD (for example, 3.3 V) to the ground potential GND via the pMOS transistor M2, electrical circuit element 20a, and the light-emitting element 50a. On the other hand, when the output is at low level (when the nMOS transistor M1 is on), since the potential at the terminal of electrical circuit element 20a which is located on the semiconductor integrated circuit chip 10a side becomes equal to the ground potential GND, no current flows in the light-emitting element 50a. Therefore, no optical signal is generated.

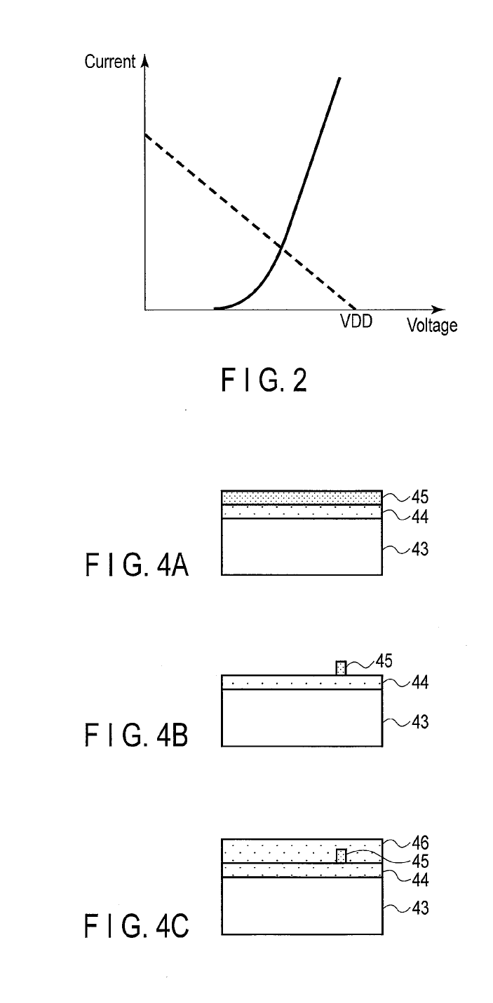

It is possible to obtain a current which flows when the output is at high level from the current-voltage characteristic of electrical circuit element 20a as a resistive element and the current-voltage characteristic of the light-emitting element 50a as a diode element. That is, as shown in FIG. 2, this current is obtained as a current at the intersection between the current-voltage characteristic (the broken line in FIG. 2) of electrical circuit element 20a which is represented by

I=(VDD−V)/R (1)

and the current-voltage characteristic (the solid line in FIG. 2) of the light-emitting element 50a which is represented by

I=Is×[exp{V/(n×Vt)}−1] (2)

where I is a current in the light-emitting element 50a and electrical circuit element 20a, V is the voltage of the light-emitting element 50a, VDD is the power supply voltage of semiconductor integrated circuit chip 10a, R is the resistance of electrical circuit element 20a, Is is a saturated current, n is a constant, and Vt is a thermal voltage. Since this current is determined by the resistance R (corresponding to the gradient of the broken line in FIG. 2) of electrical circuit element 20a, electrical circuit element 20a functions as a current limiting element.

In this case, applying a voltage greater than or equal to the rising voltage of the diode to the light-emitting element 50a will rapidly and exponentially increase a current according to equation (2) given above. For this reason, if the output circuit of semiconductor integrated circuit chip 10a is directly connected to the light-emitting element 50a without using electrical circuit element 20a, a large current (for example, 100 mA) flows from the power supply potential VDD to the light-emitting element 50a. This may damage the pMOS transistor M2 or the electrical interconnection connected to it or destruct the light-emitting element 50a. That is, this embodiment can improve the reliability of the circuit by adding electrical circuit element 20a as a current limiting element.

On the semiconductor integrated circuit chip 10b side, the light-receiving element 50b receives an optical signal and generates a current signal. Electrical circuit element 20b converts it into a voltage signal. The interface circuit of semiconductor integrated circuit chip 10b then receives the signal. That is, electrical circuit element 20b functions as a current/voltage conversion element.

Upon receiving an optical signal corresponding to high level from the light-emitting element 50a, the light-receiving element 50b and electrical circuit element 20b generate a voltage signal corresponding to high level. If this signal exceeds a threshold in the interface circuit of semiconductor integrated circuit chip 10b, the signal is discriminated as a high-level signal. Upon receiving an optical signal corresponding to low level from the light-emitting element 50a, the light-receiving element 50b and electrical circuit element 20b generate a voltage signal corresponding to low level. If this signal does not exceed the threshold in the interface circuit of semiconductor integrated circuit chip 10b, the signal is discriminated as a low-level signal.

Assume that the slope efficiency of the light-emitting element 50a is 0.5 W/A, the optical coupling efficiency (including the loss of the optical waveguide 42) from the light-emitting element 50a to the light-receiving element 50b is 3 dB, the conversion efficiency of the light-receiving element 50b is 0.6 A/W, and the threshold of the reception circuit is 0.6 V. If, for example, a current of 8 mA flows in the transmission circuit when its output is at high level, the light-emitting element 50a generates an optical signal of 4 mW, and the light-receiving element 50b receives an optical signal of 2 mW. The light-receiving element 50b then generates a current signal of 1.2 mA, and electrical circuit element 20b generates a voltage signal of 1.2 V. This signal is larger than the threshold in the reception circuit, and hence is discriminated as a high-level signal. If no current flows when the output of the transmission circuit is at low level, the voltage signal generated by electrical circuit element 20b is 0 V. This signal is smaller than the threshold in the reception circuit, and hence is discriminated as a low-level signal.

In general, when a resistive element is used as a current/voltage conversion element, it is not possible to transmit a signal at a rate higher than the cutoff frequency (1/2 πCR) determined by a parasitic capacitance C of the light-receiving element 50b and a resistance R of the resistive element. This embodiment, however, uses the light-receiving element 50b having a small parasitic capacitance (for example, 10 fF), which is formed in the silicon interposer 60, and hence the cutoff frequency is about 16 GHZ even when a current/voltage conversion element of 1 kΩ is used. It is therefore possible to transmit a signal at a rate greater than or equal to 10 Gbps.

Referring to FIG. 1C, the power supply voltages for all semiconductor integrated circuit chips 10a and 10b and the light-receiving element 50b are set to VDD. However, these voltages may be changed as needed. If, for example, a GaAs-based material is used for the light-emitting element 50a, the forward voltage of the diode is, for example, 2 V. In this case, the power supply voltage for semiconductor integrated circuit chip 10a is preferably 3.3 V or more. When a voltage of 1.2 V is generated in electrical circuit element 20b, as described above, the voltage across the light-receiving element 50b decreases by 1.2 V. This may lead to the inability to apply a sufficient reverse bias voltage to the light-receiving element 50b. For this reason, the power supply voltage for semiconductor integrated circuit chip 10b is preferably 3.3 V. On the other hand, the interface circuit of semiconductor integrated circuit chip 10b preferably has sensitivity to a smaller voltage amplitude (has a lower threshold voltage), and the power supply voltage is preferably, for example, 1.2 V.

### <Effect>

Both the semiconductor integrated circuit chip 10 and the silicon interposer 60 use silicon substrates, and hence have almost the same thermal expansion characteristics. This makes it possible to prevent chip breakage and electrical connection breakdown due to thermal strain when circuit operation raises the chip temperature and to suppress deterioration in reliability.

The semiconductor integrated circuit chips 10 are mounted on the silicon interposer 60 so as to overlap the optical semiconductor elements 50 and the electrical circuit elements 20 when viewed from above. This can minimize the area necessary for the transmission or reception of optical signals. That is, it is possible to reduce the cost of an optoelectronic integrated package module.

In the optoelectronic integrated package module of this embodiment, the silicon interposer 60 incorporates the electrical circuit elements 20 and the optical semiconductor elements 50. This makes it possible to complete the optoelectronic integrated package module by only mounting the semiconductor integrated circuit chips 10 on the silicon interposer 60 and electrically connecting them. It is therefore easy to align the semiconductor integrated circuit chips 10 when mounting them. In addition, temperature changes do not cause the problems of the optical axis shift between the optical semiconductor elements 50 and the optical waveguides 42 and the like. That is, this module has excellent reliability.

The electrical circuit elements 20 are formed in advance in the silicon interposer 60. This can suppress variations in parasitic impedance accompanying variations in solder amount or mounting position shifts as compared with when, for example, mounting discrete electrical circuit elements on the silicon interposer 60 by soldering. It is therefore possible to transmit high-quality signals.

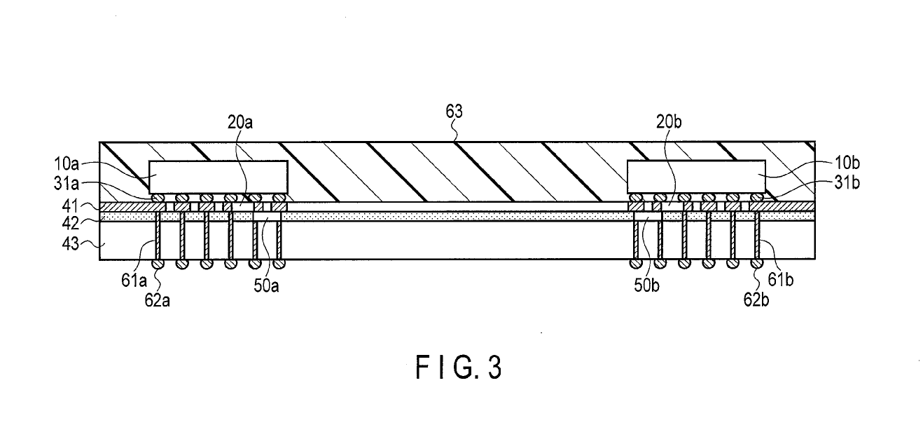

As shown in FIG. 3, the optoelectronic integrated package module is preferably packaged by forming through silicon electrodes (through-silicon vias [TSVs]) 61, i.e., 61a and 61b, and soldering bumps 62, i.e., 62a and 62b, which are connected to the electrical interconnections 41, on the silicon interposer 60 and protecting their surfaces with a mold resin 63. This makes it possible to mount the optoelectronic integrated package module of this embodiment on an external substrate. Consequently, it is possible to improve the operation performance of system equipment such as a server by embedding the optoelectronic integrated package module of this embodiment in the system equipment.

This embodiment uses the silicon interposer 60, in which the optical semiconductor elements 50 are formed, to place the optical semiconductor elements 50 near the semiconductor integrated circuit chips 10. This shortens the distances from the semiconductor integrated circuit chips 10 to the optical semiconductor elements 50, and hence can reduce the intensity of electromagnetic noise emitted from the electrical interconnections 41 and prevent operation errors in the electronic devices due to electromagnetic noise interference. That is, it is possible to improve the operation reliability. In addition, it is possible to transmit high-quality signals by reducing the influences of attenuation in the electrical interconnections 41 (transmission lines) and reflection at the reception ends. Although the shorter the length of the electrical interconnection 41, the better, it is preferable to set the length to 1/10 or less of the wavelength of a transmission signal.

As described above, the optoelectronic integrated package module of this embodiment allows high-speed, low-noise optical signal transmission between semiconductor integrated circuit chip 10a on the transmission side and semiconductor integrated circuit chip 10b on the reception side. Since the semiconductor integrated circuit chips 10 are mounted on the silicon interposer 60 and have almost the same thermal expansion characteristics, it is possible to suppress deterioration in reliability. The optoelectronic integrated package module can be implemented by the simple process of only mounting the semiconductor integrated circuit chips 10 on the silicon interposer 60, and is free from the problems of the optical axis shift between the optical semiconductor elements 50 and the optical waveguides 42 and the like. Therefore, this module has excellent reliability. The semiconductor integrated circuit chips 10 are mounted on the silicon interposer 60 so as to overlap the optical semiconductor elements 50 when viewed from above. This makes it possible to reduce the cost of the optoelectronic integrated package module and facilitate mounting by minimizing the mounting area.

In addition, since the electrical circuit elements 20 are formed in the silicon interposer 60, it is possible to suppress variations in parasitic and transmit high-quality signals. Furthermore, placing the optical semiconductor elements 50 near the semiconductor integrated circuit chips 10 makes it possible to reduce the intensity of electromagnetic noise emitted from the electrical interconnections 41 and improve the operation reliability of the electronic devices. At the same time, this makes it possible to transmit high-quality signals by reducing the influences of attenuation in the electrical interconnections 41 and reflection at the reception ends.

### <Manufacturing Method>

A method of manufacturing the optoelectronic integrated package module of this embodiment will be described below.

First of all, the optical waveguide 42 is formed in the silicon interposer 60. More specifically, as shown in FIG. 4A, a silicon oxide film 44 and a silicon layer 45 are sequentially formed on the silicon substrate 43 by chemical vapor deposition (CVD). As shown in FIG. 4B, the silicon layer 45 is then patterned. As shown in FIG. 4C, a silicon oxide film 46 is formed by CVD. Lastly, the surface of the resultant structure is planarized by chemical mechanical polishing (CMP).

Note that an silicon-on-insulator (SOI) substrate having an SiO₂ film inserted between a silicon substrate and a surface silicon film may be used as the silicon substrate 43 from the first. In this case, since a single-crystal Si film can be used as the surface silicon film, it is possible to form an optical waveguide with a small optical loss. In contrast to this, if a silicon layer is formed by CVD as described above, the surface silicon film is a poly-Si film or amorphous Si film. Consequently, the optical loss of the optical waveguide increases as compared with the use of a single-crystal Si film. Note that as a material for the core of the optical waveguide 42, it is possible to use, for example, single-crystal Si, microcrystalline Si, poly-Si, amorphous Si, SiN, SiON, or a polymer-based material.

The multilayer structure formed on the compound semiconductor substrate is transferred onto the silicon substrate 43 and patterned to form the ring-like optical semiconductor elements 50 on the silicon substrate.

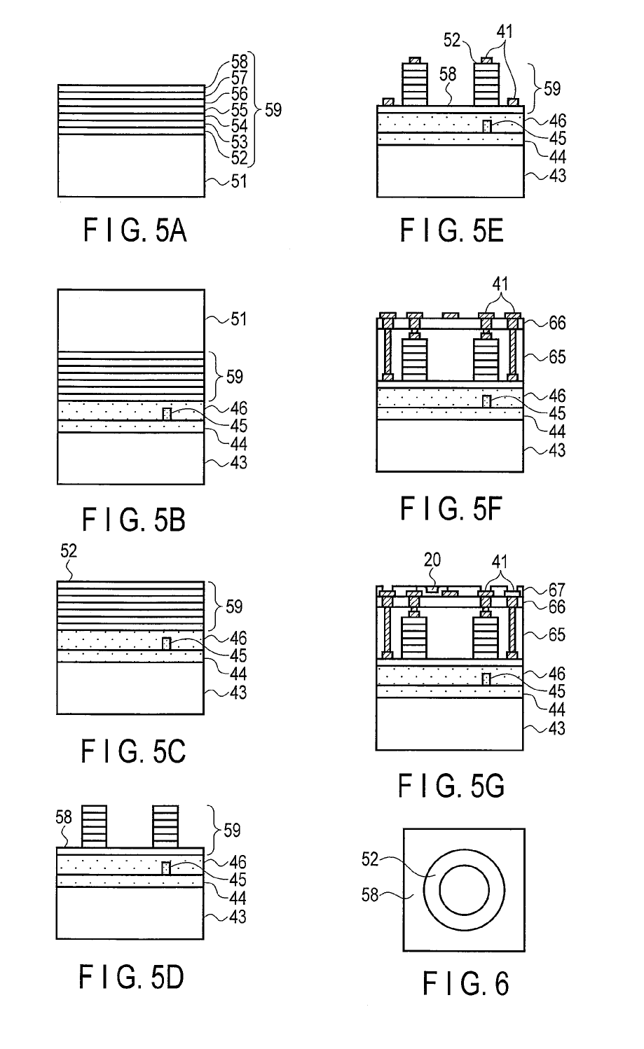

More specifically, as shown in FIG. 5A, after an n-GaAs buffer layer and an n-AlGaAs etching stop layer (neither of which is shown) are formed on an n-GaAs substrate 51 by metal organic chemical vapor deposition (MOCVD), a multilayer structure 59 is formed on the resultant structure. The multilayer structure 59 includes an n-GaAs contact layer 52, an n-AlGaAs cladding layer 53, an n-GaAs light confining layer 54, a GaAs active layer 55, a p-GaAs light confining layer 56, a p-AlGaAs cladding layer 57, and a p-GaAs contact layer 58.

As shown in FIG. 5B, the surface (on the multilayer structure 59 side) of this compound semiconductor substrate and the surface of the silicon substrate (which is located on the side where the optical waveguide 42 is formed) described above are activated by an Ar plasma process. These substrates are made to face each other and come into contact with each other and are joined by thermocompressing bonding in an inert gas. As shown in FIG. 5C, the n-GaAs substrate 51, the n-GaAs buffer layer, and the n-AlGaAs etching stop layer are then removed by wet etching to expose the n-GaAs contact layer 52.

As shown in FIG. 5D, the multilayer structure 59 is patterned in the form of a ring until the p-GaAs contact layer 58 is exposed. FIG. 6 is a plan view of the resultant structure. As shown in FIG. 5E, the electrical interconnections (electrodes) 41 are formed on the n-GaAs contact layer 52 and the p-GaAs contact layer 58.

The optical semiconductor element 50 formed in this manner can function as both a light-emitting element and a light-receiving element. This indicates that the light-emitting element 50a and the light-receiving element 50b can be simultaneously formed. That is, making the light-emitting element 50a and the light-receiving element 50b have the same structure allows to form them by one crystal growth process. In addition, the shapes into which the light-emitting element 50a and the light-receiving element 50b are patterned may be changed as needed to be suitable for the respective operations.

As is obvious from FIG. 5E, the n-GaAs contact layer 52 differs in surface height from the p-GaAs contact layer 58. As shown in FIG. 5F, a silicon oxide film 65 is formed by CVD, and its surface is planarized by CMP. The surface is then coated with photosensitive polyimide 66, which is then patterned. Thereafter, electrical interconnections are formed by patterning. This preferably extracts the electrical interconnections 41 to the same height, which are connected to the n-GaAs contact layer 52 and the p-GaAs contact layer 58, and forms the electrical interconnections 41 on the silicon interposer 60.

As shown in FIG. 5G, Ta and Si films are then formed by sputtering, and the Si film is oxidized by oxygen plasma to form a Ta—SiO₂ film. Thereafter, the electrical circuit elements 20 formed from thin film resistive elements are formed by patterning, and a photosensitive polyimide film 67 is formed and patterned. This protects and insulates the surface of the silicon interposer 60 and forms electrical connection terminals.

Lastly, the semiconductor integrated circuit chips 10 are mounted on the silicon interposer 60 by reflow to complete the optoelectronic integrated package module. In a reflow process, for example, an underfill resin or the like is preferably used to reinforce the junction.

### Second Embodiment

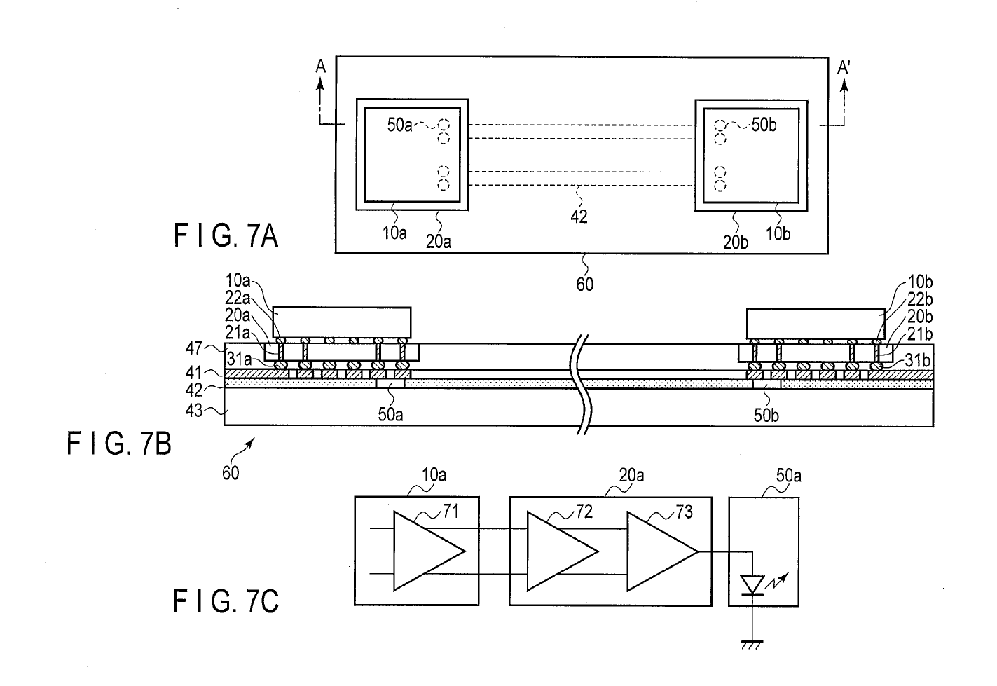

FIGS. 7A, 7B, and 7C are views for explaining the schematic arrangement of an optoelectronic integrated package module according to the second embodiment. FIG. 7A is a plan view of the optoelectronic integrated package module. FIG. 7B is a sectional view taken along A-A′ in FIG. 7A. FIG. 7C is a circuit diagram showing the optoelectronic integrated package module on the transmission side. Note that the same reference numbers as in FIGS. 1A, 1B, and 1C denote the same parts in FIGS. 7A, 7B, and 7C, and a detailed description of them will be omitted.

### <Arrangement/Manufacturing Method>

This embodiment differs from the first embodiment described above in the arrangement of electrical circuit elements 20. The electrical circuit element 20 in this embodiment is not a simple thin film resistive element but is a driver IC (driver circuit element) or receiver IC (receiver circuit element) having a size of 12 mm×12 mm and a thickness of 50 μm, which is manufactured by, for example, a 90 nm generation CMOS process. That is, an electrical circuit element 20a is a driver IC which drives a light-emitting element 50a based on the electrical signal output from a semiconductor integrated circuit chip 10a. An electrical circuit element 20b is a receiver IC which amplifies the electrical signal output from a light-receiving element 50b and transmits the signal to semiconductor integrated circuit chip 10b. Note that the electrical circuit element 20 may be a transceiver IC having circuits for both a transceiver IC and a receiver IC.

The semiconductor integrated circuit chips 10 and the electrical circuit elements 20 are different chips manufactured by different processes for the following reason. That is, a semiconductor integrated circuit chip such as a system LSI mainly consisting of logic circuits is required to achieve a reduction in cost, an increase in speed, and a reduction in power consumption. For this reason, the most advanced process is used. In contrast to this, the electrical circuit element 20 such as a driver IC or receiver IC mainly consisting of analog circuits requires a high power supply voltage which cannot be used in the most advanced process. In addition, the advanced process causes the short channel effect and variations in threshold in MOS transistors. For this reason, an old-generation process is used.

The electrical circuit elements 20 are formed on bumps 31, i.e., 31a and 31b, each having a diameter of 50 μm, arranged on a silicon interposer 60 at a pitch of 100 μm, and are electrically connected to electrical interconnections 41 of the silicon interposer 60. The electrical circuit element 20 is embedded in the silicon interposer 60 up to the surface height of the electrical circuit element 20 by means of a polyimide resin 47. Assume that covering the lower layer and the side surfaces with an insulator exposes only the surface (electrical connection terminal) of the electrical circuit element 20 on the surface of the silicon interposer 60. This protects the electrical circuit elements 20, and hence prevents the electrical circuit elements 20 from being damaged by heating and physical impact when mounting the semiconductor integrated circuit chips 10 (described later).

Via interconnections 21, i.e., 21a and 21b, are formed in the electrical circuit elements 20. This forms electrical interconnection paths extending from the surfaces (first principal surfaces) of the electrical circuit elements 20 to the element formation layers in the electrical circuit elements 20 and electrical interconnection paths extending from the surfaces (first principal surfaces) to the surfaces (second principal surfaces) on the silicon interposer side. Semiconductor integrated circuit chips 10 are mounted on the electrical circuit elements 20. The semiconductor integrated circuit chips 10 are electrically connected to Cu micro-bumps 22, i.e., 22a and 22b, each having a diameter of 25 μm, formed in the surfaces of the via interconnections 21 at a pitch of 50 μm. With this arrangement, some electrical input/output terminals of the semiconductor integrated circuit chips 10 are connected to circuit elements (for example, transistors and resistive elements) in the electrical circuit elements 20. Other electrical input/output terminals of the semiconductor integrated circuit chips 10 are connected to the electrical interconnections 41 of the silicon interposer 60.

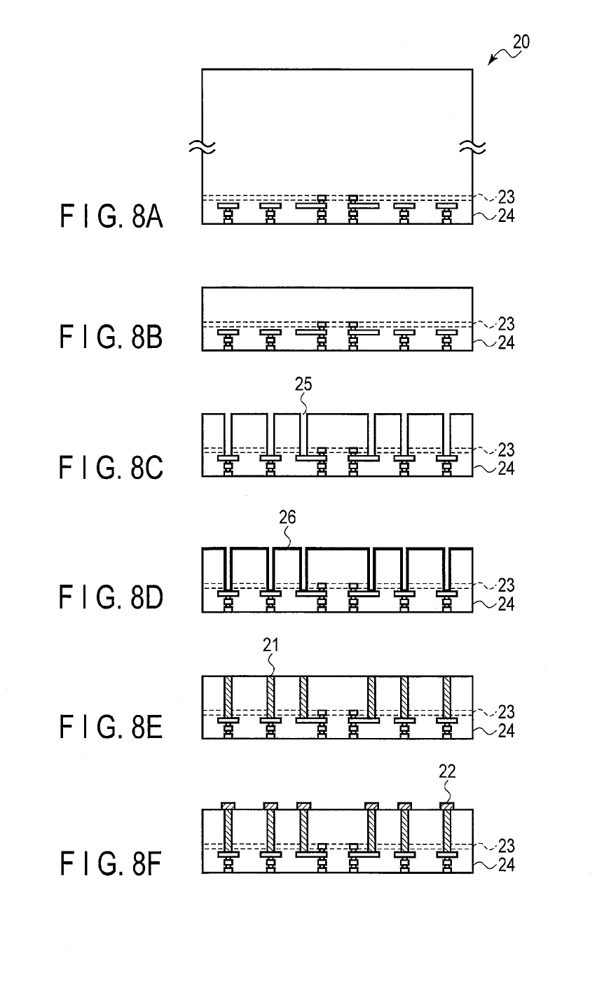

The via interconnections 21 of the electrical circuit element 20 are formed in the manner shown in FIGS. 8A, 8B, 8C, 8D, 8E, and 8F.

The back surface of a wafer before the electrical circuit element 20 is cut by back grinding as shown in FIG. 8A is thinned by grinding to the degree that the distance from an element formation layer 23 to the back surface becomes about 50 μm, as shown in FIG. 8B. Thereafter, as shown in FIG. 8C, 10 μm diameter via holes 25 extending from the back surface to a multilayer interconnection layer 24 by etching.

As shown in FIG. 8D, after an SiON film as an insulating film and Ti/TiN as a barrier metal are sequentially formed on the inner wall of each via hole 25, a Cu seed metal 26 is formed by sputtering. The via hole 25 is then filled with Cu by electrolytic plating, and the surface of the hole is planarized by CMP, thereby forming the via interconnection 21, as shown in FIG. 8E.

As shown in FIG. 8F, the Cu micro-bumps 22 are formed by forming a Cu seed metal again, applying and patterning a resist, electrolytically plating the surface, and removing the resist and the Cu seed metal. Finally, dicing is performed to complete the electrical circuit element 20 in and on which the via interconnections 21 and the Cu micro-bumps 22 are formed.

In this case, the pad electrode surfaces of the semiconductor integrated circuit chips 10 are plated with Ni/Au, and the surfaces of the Cu micro-bumps 22 of the electrical circuit element 20 are plated with Sn—Ag. This can solder the pad electrodes of the semiconductor integrated circuit chip 10 to the Cu micro-bumps 22 of the electrical circuit element 20 by mounting the pad electrodes on the Cu micro-bumps 22 and performing thermocompressing bonding. Note that a resin material such as non-conductive paste (NCP) may be used at the time of thermocompressing bonding.

The electrical circuit element 20 may be smaller in circuit size and circuit area than the semiconductor integrated circuit chip 10. However, to mount the semiconductor integrated circuit chip 10, the electrical circuit element 20 has a larger external size than the semiconductor integrated circuit chip 10. This allows to ensure a sufficient circuit formation region in the electrical circuit element 20. This makes it possible to decouple the power supplied to the semiconductor integrated circuit chip 10 and the electrical circuit element 20 by forming an on-chip capacitor in the electrical circuit element 20. This can reduce power supply noise and improve the signal quality.

Although the electrical circuit element 20 need not always have a larger size than the semiconductor integrated circuit chip 10, the electrical circuit element 20 preferably has a larger size than at least the electrical input/output terminal region formed on the semiconductor integrated circuit chip 10. This makes it possible to connect all the electrical input/output terminals formed on the semiconductor integrated circuit chip 10 to the electrical circuit element 20.

### <Effects>

In the optoelectronic integrated package module of this embodiment, electrical circuit element 20a drives the light-emitting element 50a based on the electrical signal output from semiconductor integrated circuit chip 10a, and electrical circuit element 20b amplifies the electrical signal output from the light-receiving element 50b and transmits the signal to semiconductor integrated circuit chip 10b. This can implement high-speed, low-noise optical signal transmission from semiconductor integrated circuit chip 10a to semiconductor integrated circuit chip 10b.

In the optoelectronic integrated package module of this embodiment, the semiconductor integrated circuit chips 10 are mounted on the electrical circuit elements 20, and are electrically connected to them via the Cu micro-bumps 22 and the via interconnections 21. If, for example, the Cu microbump 22 has a height of 10 μm and the via interconnection 21 has a height of 50 μm, the length of the electrical interconnection connecting the semiconductor integrated circuit chip 10 to the electrical circuit element 20 is 60 μm. This is about 0.004 times, for example, the wavelength (15 mm) of a transmission signal having a frequency of 10 GHz in a dielectric element with a specific dielectric constant of 4. That is, since the length of the transmission line is sufficiently smaller than the wavelength of a transmission signal, the influences of attenuation in the transmission lines and reflection at the reception ends are small.

For this reason, as shown in FIG. 7C, when a transmission circuit 71 of semiconductor integrated circuit chip 10a transmits a signal to electrical circuit element 20a, an unterminated reception circuit 72 can receive the signal. A driving circuit 73 then can drive the light-emitting element 50a. This can reduce power consumption because there is no need to supply a current large enough to make a terminal resistor generate the reception voltage of the reception circuit 72. In order to regard the influences of attenuation in a transmission line and reflection at the reception end small, the distance of an electrical interconnection is preferably 1/10 or less of the wavelength of a transmission signal.

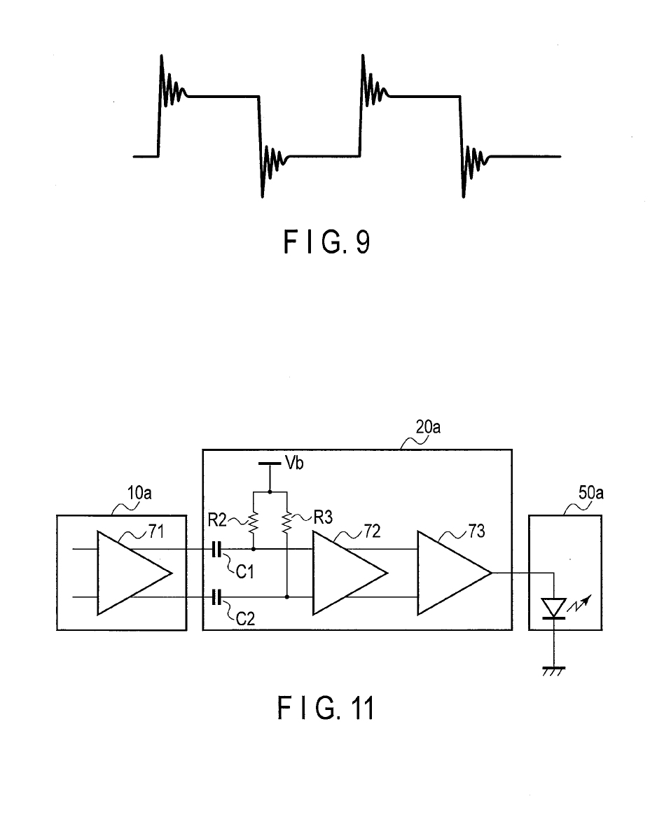

In this case as well, as shown in FIG. 9, ringing occurs at portions where transitions such as the rising and falling edges of an electrical signal occur. This is because the portions where the transitions occur include spectrum components having higher frequencies than the transmission signal, and the components are reflected. Such reflection creates the problem of producing electromagnetic interference (EMI), i.e., considerable electromagnetic noise is emitted and enters other devices and elements, causing an operating error. That is, an optoelectronic integrated package module using only an unterminated reception circuit for the reduction of power consumption has low practicability.

For this reason, this embodiment uses the silicon interposer 60, in which the optical semiconductor elements 50 are formed, to place the optical semiconductor elements 50 near the semiconductor integrated circuit chips 10. This shortens the lengths of the electrical interconnections 41 connecting the semiconductor integrated circuit chips 10 to the optical semiconductor elements 50, and hence can reduce the intensity of electromagnetic noise emitted from the electrical interconnections 41. This can implement a low power consumption optoelectronic integrated package module having high practicability. Although the shorter the length of the electrical interconnection 41, the better, it is preferable to set the length to 1/10 or less of the wavelength of a transmission signal. Obviously, with regard to the electrical interconnections 41 connecting the semiconductor integrated circuit chips 10 to the optical semiconductor elements 50, it is possible to reduce the influences of attenuation in the transmission lines and reflection at the reception ends.

As described above, the optoelectronic integrated package module of this embodiment allows high-speed, low-noise optical signal transmission between semiconductor integrated circuit chips 10a and 10b as in the first embodiment. Since the semiconductor integrated circuit chips 10 are mounted on the silicon interposer 60 and have almost the same thermal expansion characteristics, it is possible to suppress deterioration in reliability. The optoelectronic integrated package module can be implemented by the simple process of only mounting the semiconductor integrated circuit chips 10 on the silicon interposer 60, and is free from the problems of the optical axis shift between the optical semiconductor elements 50 and the optical waveguides 42 and the like. Therefore, this module has excellent reliability. The semiconductor integrated circuit chips 10 are mounted on the silicon interposer 60 so as to overlap the optical semiconductor elements 50 when viewed from above. This makes it possible to reduce the cost of the optoelectronic integrated package module by minimizing the mounting area.

In addition, since the electrical circuit elements 20 are formed in the silicon interposer 60, it is possible to suppress variations in parasitic impedance and transmit high-quality signals. Furthermore, it is possible to improve the operation reliability of the electronic devices by reducing the intensity of electromagnetic noise emitted from the electrical interconnections 41. At the same time, this makes it possible to transmit high-quality signals by reducing the influences of attenuation in the electrical interconnections 41 and reflection at the reception ends.

In addition, in the optoelectronic integrated package module of this embodiment, since the semiconductor integrated circuit chips 10 and the electrical circuit elements 20 are stacked on each other, and the electrical circuit elements 20 receive signals via the unterminated reception circuits 72, it is possible to reduce power consumption. Furthermore, placing the optical semiconductor elements 50 near the semiconductor integrated circuit chips 10 can reduce the influence of electromagnetic noise emission due to the occurrence of ringing by the unterminated reception circuits 72. This makes it possible to implement an optoelectronic integrated package module having high practicability.

### Third Embodiment

FIGS. 10A and 10B are views for explaining the schematic arrangement of an optoelectronic integrated package module according to the third embodiment. FIG. 10A is a plan view. FIG. 10B is a sectional view taken along A-A′ in FIG. 10A. Note that the same reference numbers as in FIGS. 1A and 1B denote the same parts in FIGS. 10A and 10B, and a detailed description of them will be omitted.

In the optoelectronic integrated package module shown in FIGS. 1A and 1B, the semiconductor integrated circuit chips 10 are mounted on the silicon interposer 60 so as to overlap the optical semiconductor elements 50 when viewed from above. In contrast to this, in this embodiment, as shown in FIGS. 10A and 10B, optical semiconductor elements 50 are arranged outside semiconductor integrated circuit chips 10 when viewed from above. This facilitates heat dissipation from the optical semiconductor elements 50. In this case, in order to sufficiently reduce the influences of attenuation in transmission lines and reflection at the reception ends, the length of electrical interconnections is preferably 1/10 or less of the wavelength of a transmission signal.

This arrangement can reduce the influence of heat generation from the semiconductor integrated circuit chips 10 and improve the temperature characteristics of the optical semiconductor elements 50 as well as obtaining the same effects as those of the second embodiment described above.

### Fourth Embodiment

FIG. 11 is a circuit diagram for explaining an optoelectronic integrated package module according to the fourth embodiment, showing an example of capacitive coupling between the transmission circuit of a semiconductor integrated circuit and the reception circuit of an electrical circuit element.

In the optoelectronic integrated package module shown in FIGS. 7A, 7B, and 7C, the transmission circuit 71 of semiconductor integrated circuit chip 10a is DC-coupled to the reception circuit 72 of electrical circuit element 20a. In contrast to this, in this embodiment, as shown in FIG. 11, they are capacitively coupled to each other by means of capacitors C1 and C2. With this arrangement, when the power supply voltage of a transmission circuit 71 of a semiconductor integrated circuit chip 10a is higher than that of a reception circuit 72 of an electrical circuit element 20a, it is possible to prevent an element from being destroyed by a DC overvoltage applied to the input transistor of the reception circuit 72 of electrical circuit element 20a. This can improve reliability.

Note that when the transmission circuit 71 of semiconductor integrated circuit chip 10a is capacitively coupled to the reception circuit 72 of electrical circuit element 20a, it is preferable to apply a predetermined input DC level (Vb) to the reception circuit 72 by means of resistors R2 and R3, as shown in FIG. 11. For this reason, a resistance of R2+R3 is inserted between the differential inputs. However, setting the sum of resistances R2 and R3 to, for example, the order of kilo ohms can set the current flowing in resistors R2 and R3 to the order of microamperes. It is therefore still possible to obtain the effect of reducing power consumption by reception at an unterminated circuit.

### Fifth Embodiment

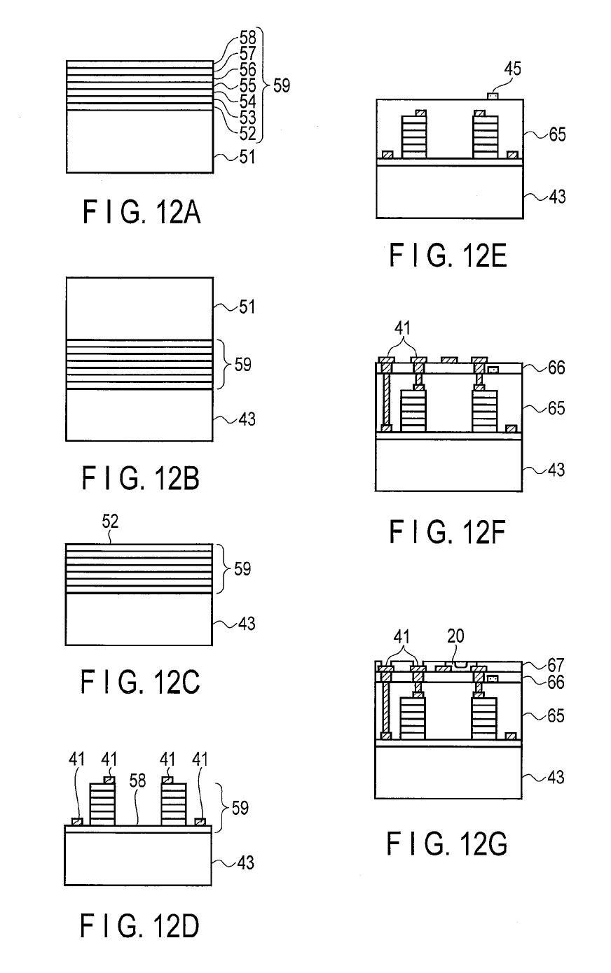

In the first embodiment, as shown in FIGS. 5A to 5G, the optical semiconductor element 50 is formed on the silicon substrate 43 by transferring the multilayer structure 59 formed on the n-GaAs substrate 51 onto the silicon substrate 43 in which the optical waveguides 42 are formed and patterning the resultant structure. In contrast to this, as shown in FIGS. 12A to 12G, this embodiment can directly form an optical semiconductor element 50 on a silicon substrate 43.

That is, as shown in FIG. 12A, a multilayer structure 59 is formed on an n-GaAs substrate 51. As shown in FIG. 12B, the surface (on the multilayer structure 59 side) of this compound semiconductor substrate and the surface of a silicon substrate 43 are activated by an Ar plasma process. These substrates are made to face each other and come into contact with each other and are joined by thermocompressing bonding in an inert gas. As shown in FIG. 12C, the n-GaAs substrate 51, an n-GaAs buffer layer, and an n-AlGaAs etching stop layer are then removed by wet etching to expose an n-GaAs contact layer 52.

As shown in FIG. 12D, the multilayer structure 59 is patterned in the form of a ring until a p-GaAs contact layer 58 is exposed. In addition, electrical interconnections (electrodes) 41 are formed on the n-GaAs contact layer 52 and the p-GaAs contact layer 58. Thereafter, as shown in FIG. 12E, a silicon oxide film 65 is formed by CVD until the optical semiconductor element 50 is embedded, and the surface of the resultant structure is planarized by CMP. A core 45 is formed by forming and patterning a silicon layer (poly-Si layer).

As shown in FIG. 12F, photosensitive polyimide 66 is applied to the silicon oxide film 65 and patterned to form the electrical interconnections 41 connected to the n-GaAs contact layer 52 and the p-GaAs contact layer 58.

Finally, as shown in FIG. 12G, Ta and Si films are then formed by sputtering, and the Si film is oxidized by oxygen plasma to form a Ta—SiO₂ film. Thereafter, the electrical circuit elements 20 formed from thin film resistive elements are formed by patterning. In addition, a photosensitive polyimide film 67 is formed and patterned. This protects and insulates the surface of the silicon interposer 60 and forms electrical connection terminals.

The optical semiconductor element 50 formed in this manner is formed in direct contact with the silicon substrate 43 having better thermal conductivity than a silicon oxide film. This element allows easy heat dissipation and has excellent temperature characteristics as compared with an optical semiconductor element formed on a silicon oxide film.

### (Modification)

Note that the present invention is not limited to the respective embodiments described above.

Various types of semiconductor integrated circuit chips such as a CPU can be applied to the first semiconductor integrated circuit chip. For example, this chip may be a graphics processing unit (GPU), microcontroller, field-programmable gate array (FPGA), or controller (sensor controller or memory/storage controller) for controlling various devices.

As the thin film resistor used as the electrical circuit element 20 in the first embodiment, it is possible to use, in addition to Ta—SiO₂, other cermet materials such as Cr—SiO₂ and Nb—SiO₂. In addition, it is possible to use a high-resistance metal such as NiCr or Ta, a nitride such as TaN, and a polymer resistive element obtained by dispersing and mixing several types of carbon powders and a nonconductive powder such as silica or aluminum powder in a thermosetting resin. Furthermore, this element can be formed by, for example, a screen printing or inkjet method instead of sputtering.

Likewise, in the second embodiment, the driver IC or receiver IC used as the electrical circuit element 20 may include various types of different circuits such as a serializing circuit which converts a parallel electrical signal into a serial electrical signal and a de-serializing circuit which converts a serial electrical signal into a parallel electrical signal. Mounting a serializing circuit on the electrical circuit element 20 on the transmission side and a de-serializing circuit on the electrical circuit element 20 on the reception side can transmit a plurality of electrical inputs and outputs upon converting them into a small number of optical signals. In addition, the second embodiment has exemplified the case in which the semiconductor integrated circuits are mounted on the electrical circuit elements 20. However, other chips and modules may be further stacked on the semiconductor integrated circuit chips.

In the optoelectronic integrated package module shown in FIGS. 1A, 1B, and 10, the inverter circuit is used as the interface circuit of the semiconductor integrated circuit chip 10. However, it is possible to use various other types of circuits. For example, it is possible to use other CMOS circuits such as NAND and NOR gates. In addition, it is possible to use an open-drain circuit having, as an output terminal on the transmission side, the drain terminal of a pMOS transistor whose source is connected to the power supply potential or of an nMOS transistor whose source is connected to ground, and having, as an input terminal on the reception side, one terminal of a resistor whose other terminal is connected to ground or the power supply. In addition to these, various types of interface circuits can be used. Likewise, in the optoelectronic integrated package module shown in FIGS. 1A, 1B, and 1C, the interface circuit of the semiconductor integrated circuit chip 10 is a single-end circuit. However, this circuit may be a differential circuit.

In the optoelectronic integrated package module shown in FIGS. 1A, 1B, and 1C, the transmission circuit of semiconductor integrated circuit chip 10a and the light-emitting element 50a are DC-coupled to each other via the electrical circuit element 20, so are the reception circuit of semiconductor integrated circuit chip 10b and the light-receiving element 50b. However, this embodiment is not limited to this, and they can be capacitively coupled to each other by means of capacitors. In this case, however, it is preferable to separately prepare a circuit for applying DC voltages to the light-emitting element 50a and the light-receiving element 50b. This arrangement makes it possible to connect the semiconductor integrated circuit chips 10 to the optical semiconductor elements 50 regardless of the power supply voltage of the semiconductor integrated circuit chips 10.

The optoelectronic integrated package module shown in FIGS. 1A, 1B, and 1C has exemplified the circuit in which the transmission circuit of semiconductor integrated circuit chip 10a is only connected to the light-emitting element 50a via the electrical circuit element 20. However, it is preferable to separately provide a circuit for supplying a bias current to the light-emitting element 50a so as to supply a bias current which makes a voltage lower than the oscillation threshold of a laser but higher than the rising voltage of the diode. This reduces the load (differential resistance) on the diode when viewed from the transmission circuit, and hence can implement high-speed operation.

In the optoelectronic integrated package module shown in FIGS. 1A, 1B, and 10, the light-emitting element 50a is formed on the semiconductor integrated circuit chip 10a side, and the light-receiving element 50b is formed on the semiconductor integrated circuit chip 10b side. However, the light-receiving element 50b may be formed on the semiconductor integrated circuit chip 10a side, and the light-emitting element 50a may be formed on the semiconductor integrated circuit chip 10b side. Alternatively, both the light-emitting element 50a and the light-receiving element 50b may be formed on both the semiconductor integrated circuit chip 10a side and the semiconductor integrated circuit chip 10b side. This makes it possible to transmit signals from semiconductor integrated circuit chip 10b to semiconductor integrated circuit chip 10a or bidirectionally transmit signals between semiconductor integrated circuit chips 10a and 10b.

The embodiments have exemplified the case in which a GaAs-based material is used as a compound semiconductor material. However, for example, an InP-based material may be used. The wavelength to be used can be changed in accordance with the material to be used. In addition, the embodiments have exemplified the case in which the multilayer structure formed on the compound semiconductor substrate is transferred onto the silicon substrate. However, the embodiments are not limited to this. The optical semiconductor element 50 may be directly formed on the silicon substrate without using any compound semiconductor substrate. In addition, in the embodiments, the optical semiconductor element 50 has a ring-like shape. However, the optical semiconductor element 50 may have other shapes such as a disk-like shape and an elliptical shape.

The second embodiment has exemplified the via last process of forming the via interconnections 21 after the formation of the element formation layer 23 and the multi-interconnection layer 24 in the electrical circuit element 20. However, the embodiment is not limited to this. The embodiment may form the via interconnections 21 by a via middle process of forming via interconnections when the formation of the element formation layer 23 is complete or a via first process of forming via interconnections before the formation of the element formation layer 23.

In the electrical circuit element 20, each electrical interconnection path extending from the first principal surface to the second principal surface may be formed from the multi-interconnection layer formed on one principal surface in the electrical circuit element 20 and the via interconnection 21 formed to extend from the other principal surface to the multi-interconnection layer as described in the second embodiment. In addition, the electrical interconnection path may be formed from the via interconnection 21 formed to extend from the first principal surface to the second principal surface. Furthermore, the electrical interconnection path may be formed from the first via interconnection 21 formed on one principal surface in the electrical circuit element 20 and the second via interconnection 21 formed to extend from the other principal surface to the first via interconnection.

The second embodiment has exemplified the case in which the Cu micro-bumps are formed on the first principal surface side in the electrical circuit element 20. However, for example, micro-bumps, Au stud bumps, and the like may be formed. Semiconductor integrated circuit chips and electrical circuit elements may be connected to each other by thermocompressing bonding through, for example, an anisotropic conductive film (ACF).

The embodiments have exemplified the optoelectronic integrated package module which is electrically connected to the outside. However, the optoelectronic integrated package module may be optically connected to the outside. In addition, the embodiments have exemplified the optoelectronic integrated package module which can perform both transmission and reception. However, the optoelectronic integrated package module may be a module which can perform either transmission or reception. Furthermore, the manufacturing methods exemplified by the embodiments are merely examples, and the film thicknesses, shapes, techniques, materials, and the like may be changed as needed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An optoelectronic integrated package module comprising:
a silicon interposer formed on a silicon substrate, the interposer including an electrical interconnection and an optical waveguide;
an optical semiconductor element formed in the silicon interposer, the optical semiconductor element being electrically connected to the electrical interconnection and optically coupled to the optical waveguide;
an electrical circuit element formed in the silicon interposer, the electrical circuit element being electrically connected to the optical semiconductor element; and
a semiconductor integrated circuit chip mounted on the silicon interposer, the integrated circuit chip being electrically connected to the electrical circuit element to transmit an electrical signal to the optical semiconductor element via the electrical circuit element or receive an electrical signal from the optical semiconductor element via the electrical circuit element.

2. The module of claim 1, wherein the electrical circuit element comprises a resistive element.

3. The module of claim 1, wherein the electrical circuit element comprises one of a driver circuit element configured to drive the optical semiconductor element and a receiver circuit element configured to amplify an electrical signal output from the optical semiconductor element.

4. The module of claim 1, wherein the semiconductor integrated circuit chip is mounted on the silicon interposer so as to overlap the electrical circuit element and the optical semiconductor element when viewed from above.

5. The module of claim 1, wherein the optical semiconductor element is formed in contact with the silicon substrate.

6. The module of claim 1, wherein a length of the electrical interconnection configured to connect the semiconductor integrated circuit chip to the optical semiconductor element is not more than 1/10 a signal wavelength at a transmission rate of the electrical signal.

7. The module of claim 1, wherein the optical semiconductor element is placed outside the semiconductor integrated circuit chip module when viewed from above.

8. The module of claim 1, wherein a transmission circuit of the semiconductor integrated circuit chip is DC-coupled to a reception circuit of the electrical circuit element.

9. The module of claim 1, wherein a transmission circuit of the semiconductor integrated circuit chip is capacitively coupled to a reception circuit of the electrical circuit element.

10. An optoelectronic integrated package module comprising:
a silicon interposer formed on a silicon substrate, the interposer including an electrical interconnection and an optical waveguide;
a light-emitting element formed in the silicon interposer, the light-emitting element being electrically connected to the electrical interconnection and optically coupled to the optical waveguide;
a light-receiving element formed in the silicon interposer, the light-receiving element being provided separately from the light-emitting element, connected to the electrical interconnection, and optically coupled to the optical waveguide;
a first electrical circuit element formed in the silicon interposer, the first electrical circuit element being electrically connected to the light-emitting element;
a second electrical circuit element formed in the silicon interposer, the second electrical circuit element being electrically connected to the light-receiving element;
a first semiconductor integrated circuit chip mounted on the silicon interposer, the first semiconductor integrated circuit chip being electrically connected to the first electrical circuit element to transmit an electrical signal to the light-emitting element via the first electrical circuit element; and
a second semiconductor integrated circuit chip mounted on the silicon interposer, the second semiconductor integrated circuit chip being electrically connected to the second electrical circuit element to receive an electrical signal from the light-receiving element via the second electrical circuit element.

11. The module of claim 10, wherein the first electrical circuit element and the second electrical circuit element comprise resistive elements.

12. The module of claim 10, wherein the first electrical circuit element comprises a driver circuit element configured to drive the optical semiconductor element, and the second electrical circuit element comprises a receiver circuit configured to amplify an electrical signal output from the optical semiconductor element.

13. The module of claim 10, wherein the first semiconductor integrated circuit chip is mounted on the silicon interposer so as to overlap the first electrical circuit element and the first optical semiconductor element when viewed from above, and the second semiconductor integrated circuit chip is mounted on the silicon interposer so as to overlap the second electrical circuit element and the second optical semiconductor element when viewed from above.

14. The module of claim 10, wherein the first optical semiconductor element and the second optical semiconductor element are formed in contact with the silicon substrate.

15. The module of claim 10, wherein a length of the electrical interconnection configured to connect the first semiconductor integrated circuit chip to the first optical semiconductor element is not more than 1/10 a signal wavelength at a transmission rate of the electrical signal.

16. The module of claim 10, wherein the first optical semiconductor element is placed outside the first semiconductor integrated circuit chip module when viewed from above, and the second optical semiconductor element is placed outside the second semiconductor integrated circuit chip module when viewed from above.

17. The module of claim 10, wherein a transmission circuit chip of the first semiconductor integrated circuit is DC-coupled to a reception circuit of the first electrical circuit element.

18. The module of claim 10, wherein a transmission circuit of the first semiconductor integrated circuit chip is capacitively coupled to a reception circuit of the first electrical circuit element.
